(19) United States
(12) Patent Application Publication
(10) Pub. No.: US 2020/0306801 A1
(43) Pub. Date: Oct. 1, 2020

(54) Method for Regenerating Adhesive Surface of Component Holding Jig

(71) Applicant: Shin-Etsu Polymer Co., Ltd., Tokyo (JP)

(72) Inventors: Yuji Irisawa, Saitama (JP); Toshiaki Hatsumi, Saitama (JP)

(21) Appl. No.: 16/799,041

(22) Filed: Feb. 24, 2020

(30) Foreign Application Priority Data
Feb. 27, 2019 (JP) 2019-033912

(51) Int. Cl. B08B 7/00; H01L 21/683

(52) U.S. Cl. CPC B08B 7/0014; H01L 21/6836

(57) ABSTRACT

A method for regenerating an adhesive surface by removing a foreign matter adhering to the adhesive surface of a component holding jig. The method includes: disposing, on the adhesive surface, a mask member having: a surface which is in contact with the adhesive surface and has an arithmetic mean roughness of 1.0 μm or less; and an opening through which the adhesive surface is exposed; disposing a curable resin composition on the adhesive surface and on the mask member and curing the curable resin composition; and simultaneously peeling off the mask member and a cured product of the curable resin composition.

### CROSS-REFERENCE TO RELATED APPLICATIONS

This application claims priority to Japanese Patent Application No. 2019-033912 filed Feb. 27, 2019, the disclosure of which is hereby incorporated by reference in its entirety.

### BACKGROUND OF THE INVENTION

### Field of the Invention

The present invention relates to a method for regenerating an adhesive surface of a component holding jig.

### Description of Related Art

Conventionally, a holding jig for transporting an electronic component such as a ceramic capacitor, a chip resistor, a coil and a silicon wafer is provided with an elastic member capable of adhesively holding the electronic component on its adhesive surface. When the electronic component is adhered to the adhesive surface of the elastic member or detached from it, an edge of a silicon substrate or a portion of a fine metal electrode of the electronic component may be chipped or scraped. In addition, swarf of a wafer may adhere to an electronic component diced from the wafer. Thus, foreign matters such as a fragment or swarf of the electronic component may adhere to the adhesive surface of the elastic member after use.

If such foreign matters adhering to the adhesive surface of the elastic member are removed, the electronic component holding jig having the elastic member can be used again. As a method for removing such a foreign matter, for example, Japanese Unexamined Patent Publication No. 2018-85481 discloses a method for disposing a curable resin composition on an adhesive surface of an elastic member to which a foreign matter adheres and peeling a cured product to remove the foreign matter simultaneously with the cured product.

However, when the curable resin composition is disposed on the adhesive surface, the curable resin may protrude to an unnecessary area, becoming a new foreign matter. Further, when a base of the holding jig is made of a resin, the curable resin composition is bonded to it, which is a problem.

### SUMMARY OF THE INVENTION

The present disclosure has been made in view of the above circumstances. It is an object of the present disclosure to provide a method for regenerating an adhesive surface of a component holding jig capable of well removing foreign matters adhering to the adhesive surface.

The present disclosure relates to a method for regenerating an adhesive surface of a component holding jig, in which the adhesive surface is regenerated by removing a foreign matter adhering to the adhesive surface of an elastic member of the component holding jig, the method comprising: a first step for disposing, on the adhesive surface, a mask member having: a surface which is in contact with the adhesive surface and has an arithmetic mean roughness Ra of 1.0 μm or less; and an opening through which the adhesive surface is exposed; a second step for disposing a curable resin composition on the adhesive surface and on the mask member and curing the curable resin composition; and a third step for simultaneously peeling off the mask member and a cured product of the curable resin composition.

The mask member is preferably a plate-like member made of polyethylene terephthalate.

The adhesive surface is preferably made of a silicone rubber or a fluorine-based elastomer.

The curable resin composition preferably contains a polyvinyl alcohol, a polyvinyl acetate, or a vinyl acetate monomer.

In the third step, it is preferable to peel off the cured product while warming it.

The curable resin composition preferably contains a fluorine-based elastomer.

The thickness of the curable resin composition after curing is preferably 25 μm or more and 300 μm or less.

The foreign matters are a small piece containing dust, dirt, glass, metal, or silicon, and the maximum diameter of the small piece is preferably 5 mm or less.

According to the method for regenerating an adhesive surface of a component holding jig of the present disclosure, a foreign matter adhering to the adhesive surface can be well removed.

### BRIEF DESCRIPTION OF THE DRAWINGS

FIGS. 1(a)-1(d) are schematic sectional views showing a method for regenerating an adhesive surface of a component holding jig of the present invention.

### DESCRIPTION OF THE INVENTION

Embodiments of the present invention will be described in detail below. The following embodiments are presented for illustrative purposes, and the present invention is not limited in any way to the embodiments shown below.

### [Method for Regenerating an Adhesive Surface of a Component Holding Jig]

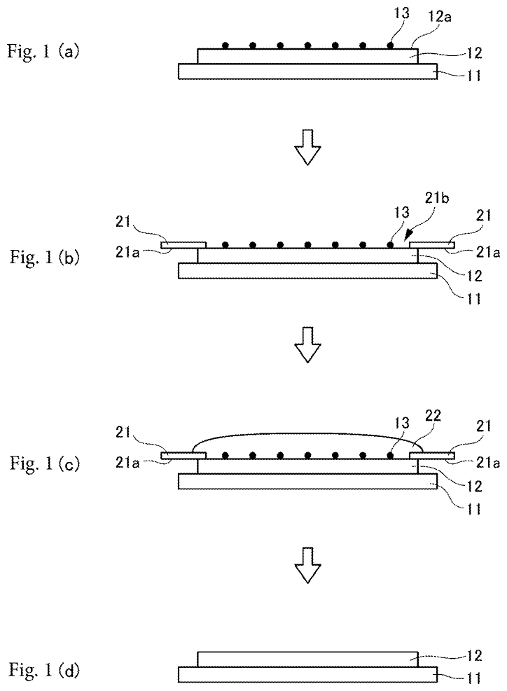

A method for regenerating an adhesive surface of a component holding jig of the present disclosure is, as shown in FIGS. 1(a)-1(d), a method for regenerating an adhesive surface 12a by removing a foreign matter 13 adhering to the adhesive surface 12a of an elastic member 12 of a component holding jig. The method comprises a first step for disposing, on the adhesive surface 12a, a mask member 21 having: a surface 21a which is in contact with the adhesive surface 12a and has an arithmetic mean roughness Ra of 1.0 μm or less; and an opening 21b through which the adhesive surface 12a is exposed; a second step for disposing a curable resin composition 22 on the adhesive surface 12a and on the mask member 21 and curing the curable resin composition 22; and a third step for simultaneously peeling off the mask member 21 and a cured product of the curable resin composition 22.

Note that the arithmetic mean roughness Ra is a value measured according to JIS B 0601-2001.

### (First Step)

Described in the present embodiment is, as shown in FIG. 1(a), a case where an elastic member 12 having an adhesive surface 12a is provided on a base 11. FIG. 1(a) shows a component holding jig after use and shows a state in which foreign matters 13 after use adhere to the adhesive surface 12a of the elastic member 12.

As shown in FIG. 1(b), the first step is a step for disposing, on the adhesive surface 12a, a mask member 21 having: a surface 21a which is in contact with the adhesive surface 12a and has an arithmetic mean roughness Ra of 1.0 μm or less; and an opening 21b through which the adhesive surface 12a is exposed.

Details of the first step will be described below.

### —Elastic Member—

The shape of the elastic member 12 may be any shape as long as the elastic member 12 has an adhesive surface capable of adhesively holding an adherend such as an electronic component. For example, the shape may be a flat shape such as a sheet-like shape or a plate-like shape. The thickness of the elastic member 12 is not particularly limited and may be set to, for example, about 0.005 mm to 5 mm. The area of the adhesive surface 12a of the elastic member is appropriately set according to its intended use. For example, it can be 100 cm² (10 cm×10 cm) to 600 cm² (20 cm×30 cm).

The entire adhesive surface 12a of the elastic member 12 may have uniform adhesiveness, or a part of the adhesive surface 12a may have non-uniform adhesiveness different from other parts. When the adhesiveness of the adhesive surface 12a is not uniform, a configuration can be exemplified in which a strong adhesive portion having a relatively strong adhesiveness, a weak adhesive portion having a relatively weak adhesiveness and a non-adhesive portion having no adhesiveness are arbitrarily arranged on the adhesive surface 12a. For example, the strong adhesive portions, which play a main role of adhesively holding the adherend, may be arranged in an array-like manner at regular intervals between the weak adhesive portions or the non-adhesive portions.

The adhesive surface 12a of the elastic member 12 has an adhesive force capable of adhesively holding an adherend such as an electronic component. The adhesive force of the strong adhesive portion is preferably 1 to 60 g/mm² and more preferably 7 to 60 g/mm² as measured by a measuring method described later from the viewpoint of sufficiently holding the adherend.

With the above adhesive force, electronic components such as a silicon wafer, a flexible printed circuit board, a glass plate for a large screen display device, a chip capacitor, a ceramic capacitor, a coil filter, a resistive element, a conductive circuit, a capacitor, an LSI and an inductor can be easily held adhesively and can be easily removed as required.

A method for measuring the above adhesive force is employed when at least a measurement portion of the adhesive surface 12a is flat. The method is performed as follows. First, the elastic member 12 having the adhesive surface 12a to be measured is horizontally fixed, and the measurement environment is set to 21±1 degrees C. and the humidity of 50±5%. Next, a stainless-steel (SUS304) contact which forms a cylinder with a diameter of 10 mm and is attached to a digital force gauge is lowered at a descent rate of 10 mm/min into contact with the adhesive surface 12a of the elastic member 12 (e.g., a strong adhesive portion). The contactor is pressed vertically against the adhesive surface 12a for 3 seconds with a pushing load of 25 g/mm². Thereafter, the contact is vertically separated from the adhesive surface 12a at an ascent rate of 180 mm/min. At this time, a pull-off load is read with the digital force gauge. This operation is performed at a plurality of places, for example, 10 places on the adhesive surface 12a, and a value obtained by arithmetically averaging the plurality of pull-off loads obtained is used as the adhesive force of the adhesive surface 12a.

Examples of a fixing device for the elastic member 12 used for measuring the adhesive force include a suction fixing device (trade name: electromagnetic chuck, KET-1530B, manufactured by KANETEC CO., LTD.) and a commercially available vacuum-suction chuck plate. As a digital force gauge to which the above contact is attached, for example, “trade name: ZP-50N, manufactured by IMADA Co., Ltd.” can be cited. The adhesive force may be measured manually or automatically, for example, by using a device such as a test stand (e.g., trade name: VERTICAL MODEL MOTORIZED STAND series, manufactured by IMADA Co., Ltd.).

The surface roughness of the adhesive surface 12a may be adjusted from the viewpoint of facilitating an attachment and detachment of an adherend. For example, it is preferable that the ten-point mean roughness Rz (JIS B 0601-1994) is adjusted to 0.5 μm to 3 μm. The ten-point average roughness Rz exemplified here is a value obtained by performing measurements under the condition of a cut-off of 0.8 mm and a measurement length of 2.4 mm and performing an arithmetic averaging of the measurement values at the plurality of points.

Here, the surface roughness of the adhesive surface 12a is a numerical value in a state where any foreign matter 13 does not adhere to the adhesive surface 12a.

The hardness (JIS K 6253 [durometer A]) of the adhesive surface 12a may be adjusted from the viewpoint of facilitating an attachment and detachment of an adherend. The hardness is preferably adjusted to, for example, about 5 to 60. When the hardness is 5 or more, sufficient adhesive force is easily obtained. When the hardness is 60 or less, the adherend can be easily removed.

In the present embodiment, the elastic member 12 is provided on the base 11 but may be used alone.

The shape of the base 11 is not particularly limited, and a shape suitable for the purpose of supporting the elastic member 12 is appropriately adopted. A material for forming the base 11 is not particularly limited and may be a metal, a resin, a ceramic or the like.

At least the adhesive surface 12a of the elastic member 12 may be formed of an adhesive composition. Examples of a rubber material constituting the adhesive surface 12a include various elastomers such as a silicone rubber, a fluorine-based elastomer, a urethane-based elastomer, a natural rubber, a styrene-butadiene copolymer elastomer and the like. Among them, a silicone rubber and a fluorine-based elastomer having excellent strength and chemical resistance are preferable. As the silicone rubber, for example, those obtained by the adhesive composition described in Japanese Patent No. 4656582 are preferred. As the fluorine-based elastomer, for example, those described in JP-A-2006-198541, JP-A-H08-199070, JP-A-2000-007835, JP-A-2001-106893 and JP-A-2003-201401 are preferable.

### —Mask Member—

The mask member 21 can be appropriately selected in accordance with the shapes of the base 11 and the elastic member 12. For example, the mask member 21 is set to an arbitrary shape such as a rectangle, an ellipse, a circle or other polygons.

The mask member 21 has an opening 21b through which the adhesive surface 12a is exposed when the mask member 21 is disposed on the adhesive surface 12a. The shape of the opening 21b is also set in accordance with the shapes of the base 11 and the elastic member 12.

By using the mask member 21, it is possible to prevent the problem in the prior art in which the resin composition protrudes from the elastic member 12, generating a new foreign matter. Further, even when the base 11 made of resin is used, the curable resin composition 22 does not adhere to it.

The mask member 21 is preferably a plate-like member made of polyethylene terephthalate, polyethylene naphthalate, or polyimide.

In the third step described later, a cured product of the curable resin composition 22 may be peeled off while being warmed. In consideration of this heating step, the mask member 21 is preferably made of a material of which heat resistance is 100 degrees C. or more. For example, polyethylene terephthalate, polyethylene naphthalate, or polyimide is preferable as the heat-resistant mask member 21.

The arithmetic mean roughness Ra of the surface 21a, which is in contact with the adhesive surface 12a, of the mask member 21 is 1.0 μm or less, more preferably 0.5 μm or less, and still more preferably 0.1 μm or less. Since the arithmetic mean roughness Ra of the surface 21a, in contact with the adhesive surface 12a, of the mask member 21 falls within the above range, the mask member 21 is well adhered to the adhesive surface 12a, preventing the curable resin composition 22 from entering between the mask member 21 and the adhesive surface 21a. Therefore, it is possible to prevent the case where the resin composition which has entered and cured therebetween becomes a new foreign matter 13 and adheres to the adhesive surface 12a.

### (Second Step)

The second step is a step for disposing the curable resin composition 22 on the adhesive surface 12a and on the mask member 21 and curing the curable resin composition 22.

Details of the second step will be described below.

### —Curable Resin Composition—

As the curable resin composition 22 disposed on the adhesive surface 12a of the elastic member 12, it is preferable that its cured product cured on the adhesive surface 12a after being disposed on the adhesive surface 12a can be easily peeled off from the adhesive surface 12a. It is also preferable that a foreign matter 13 adhering to the adhesive surface 12a can be removed together with the cured product at the time of peeling.

As used herein, “curing” refers to the conversion of a component of a curable composition into solid by physical or chemical action.

Examples of such curable resin composition 22 include a resin composition in which a resin is dispersed in a dispersion medium, and a resin precursor composition in which a resin precursor is dispersed or dissolved in a dispersion medium. Here, the term “resin” includes not only general synthetic resins but also rubbers and elastomers.

The resin composition in which a resin is dispersed in the dispersion medium includes, for example, the water-dispersible adhesive compositions exemplified below. Here, the water-dispersible adhesive compositions may be emulsion or non-emulsion. Water-dispersible adhesive compositions are preferable because they are less likely to deteriorate the adhesive surface 12a to which they are disposed or to denature a foreign matter 13 adhering to the adhesive surface 12a.

Specific water-dispersible adhesive compositions include, for example, a polyvinyl acetate dispersion liquid in which polyvinyl acetate (vinyl acetate resin) is dispersed in water, an EVA dispersion liquid in which ethylene-vinyl acetate resin copolymer (EVA) is dispersed in water, a polyvinyl alcohol dispersion liquid in which polyvinyl alcohol is dispersed in water, a latex dispersion liquid in which natural rubber (latex) is dispersed in water, an ether cellulose dispersion liquid in which ether cellulose (an ether derivative of cellulose, e.g., methyl cellulose) is dispersed in water, a starch dispersion liquid in which starch is dispersed in water, an a-olefin-based resin dispersion liquid in which copolymers of a-olefin (e.g., isobutylene) and maleic anhydride are dispersed in water, an SBR latex dispersion liquid in which latex-like styrene-butadiene rubber (SBR latex) is dispersed in water, a (meth)acrylic resin dispersion liquid in which (meth)acrylic resin is dispersed in water, a urethane-based resin dispersion liquid in which urethane-based resin is dispersed in water, an isocyanate crosslinked resin dispersion liquid in which a known aqueous polymer and isocyanate are dispersed in water, a phenol resin dispersion liquid in which phenol resin is dispersed in water, a melamine resin dispersion liquid in which melamine resin is dispersed in water, and a urea resin dispersion liquid in which urea resin is dispersed in water.

These dispersion liquids may contain known additives.

The resin composition in which a resin is dispersed in the dispersion medium includes, for example, the organic solvent adhesive compositions exemplified below. Organic solvent adhesive compositions are preferable because drying for removing an organic solvent after being disposed on the adhesive surface 12a is easier than water.

Specific organic solvent adhesive compositions include, for example, a natural rubber solution containing natural rubber in a solvent, a casein solution containing casein in a solvent, a (meth)acrylic resin solution containing (meth)acrylic resin in a solvent, a urethane-based resin solution containing urethane-based resin in a solvent, a vinyl chloride resin solution containing vinyl chloride resin in a solvent, a chloroprene rubber solution containing chloroprene rubber in a solvent, an SBR solution containing styrene-butadiene rubber in a solvent, a nitrile rubber solution containing nitrile rubber in a solvent, a nitrocellulose solution containing nitrocellulose in a solvent, a phenol resin solution containing phenol resin in a solvent, a melamine resin solution containing melamine resin in a solvent, a urea resin solution containing urea resin in a solvent, a fluorine-based elastomer solution containing fluorine-based elastomer (fluorine-containing elastomer) in a solvent, and a silicone rubber solution containing silicone rubber in a solvent.

These solutions may contain known additives. As a solvent constituting these solutions, a known organic solvent capable of dissolving or dispersing a target resin is employed.

Resin precursors refer to resin monomers or prepolymers.

In a resin precursor composition, a resin precursor reacts on an adhesive surface 12a to which it is disposed, forming a resin. Specific resin precursor compositions include, for example, a polyvinyl acetate precursor composition in which vinyl acetate is contained in water or an organic solvent, an EVA precursor composition in which ethylene and vinyl acetate are contained in water or an organic solvent, a polyvinyl alcohol precursor composition in which vinyl alcohol is contained in water or an organic solvent, a (meth)acrylic resin precursor composition in which (meth)acrylic acid or alkyl ester thereof is contained in water or an organic solvent, a urethane-based resin precursor composition in which polyol and polyisocyanate are contained in water or an organic solvent, an epoxy resin precursor composition in which epoxy resin prepolymer is contained in water or an organic solvent, a fluorine resin precursor composition in which fluorine rubber containing a cross-linking agent as well as a reinforcing filler and a cross-linking agent are contained, and a silicone-based resin precursor composition in which organopolysiloxane (of which terminals are, for example, hydroxyl or vinyl groups) and a cross-linking agent are contained in water or an organic solvent.

The resin precursor compositions may contain known additives such as a photopolymerization initiator, a thermal polymerization initiator, a curing agent and a stabilizer.

The content of the resin or the resin precursor contained in the curable resin composition may be an amount that exhibits a viscosity allowing the curable resin composition to be disposed on the adhesive surface 12a and can form a cured product on the adhesive surface 12a after curing. The specific content depends on the type of the resin or the resin precursor, but can be adjusted in the range of, for example, 0.1 to 50% by weight with respect to the total weight of the curable resin composition.

### —Method for Disposing a Curable Resin Composition on an Adhesive Surface—

The method for disposing (providing) a curable resin composition on an adhesive surface 12a of an elastic member 12 includes, for example, a method for applying (coating) the curable resin composition on the adhesive surface 12a and a method for transferring the curable composition to the adhesive surface 12a.

As a method for applying, a known method capable of coating with a desired thickness can be employed. For example, a film coater, a film applicator, a bar coater, a die coater, a spin coater, a roll coater, a curtain coater, various types of printing, dipping, spraying, casting, discharging, brushing and the like can be cited. If the viscosity of the curable resin composition is low, an enclosure (an embankment) may be provided around an application region, and the curable resin composition may be injected into the enclosure.

As shown in FIG. 1(c), a region where the curable resin composition is disposed on the adhesive surface 12a extends from the adhesive surface 12a onto the mask member 21. That is, at an end of the opening 21b, the curable resin composition and the mask member 21 are bonded and integrated. With this arrangement, after the curable resin composition is cured, the mask member 21 can be peeled off together with the cured product on the adhesive surface 12a at the same time.

The thickness of the curable resin composition disposed on the adhesive surface 12a may be appropriately set in accordance with a target thickness of the cured product. It is preferable to dispose the curable resin composition with a thickness sufficient to cover the whole of a foreign matter 13 adhered to the adhesive surface 12a. For example, it can be disposed with a thickness after curing of about 25 μm to 300 μm, preferably 50 μm to 200 μm. With such a thickness, the cured product forms a coating on the adhesive surface 12a. The coating is easily peeled off and the foreign matter 13 incorporated in the coating is also easily removed.

### —Curing Method for Curable Resin Composition—

As a method for curing the curable composition disposed on the adhesive surface 12a of the elastic member 12, for example, a known method such as a method for drying under atmospheric pressure or vacuum, a method for heating, a method for irradiating energy rays such as ultraviolet rays is employed. The degree of curing may be full cure or semi-cure. Among the above curing methods, a method for drying under atmospheric pressure or vacuum is preferable from the viewpoint of preventing deterioration of the adhesive surface 12a for the purpose of repeatedly using the elastic member 12.

The cured product after curing may be pressed to strengthen the adhesion of the cured product to the adhesive surface 12a, but it is necessary to consider the possibility that such pressing could insert a foreign matter 13 adhering to the adhesive surface 12a into the elastic member 12 or crush it.

### (Third Step)

The third step is a step for simultaneously peeling off the mask member 21 and the cured product of the curable resin composition.

Details of the third step will be described below.

### —Method for Peeling Off a Cured Product—

As a method for peeling off a cured product cured on the adhesive surface 12a from the adhesive surface 12a, there is a method for grasping an end portion of the mask member 21 and peeling off the cured product at an arbitrary rate upward or in parallel along the longitudinal direction of the cured product so that the separation proceeds.

The peeling rate is preferably, for example, about 50 to 300 mm/minute.

When the rate is within the range, the cured product is less likely to break and the cured product can be easily peeled off with a foreign matter 13 incorporated by the cured product.

When a cured resin composition containing polyvinyl alcohol, polyvinyl acetate, or vinyl acetate monomer is used, it is preferable that its cured product is warmed when the mask member 21 is peeled off. By warming, the adhesive force of the adhesive surface of a holding jig is lowered, so that the cured product is easily peeled off. Further, the cured product is softened by warming, so that the cured product does not crack. Thus, there is a low possibility that a new foreign matter is generated by breakage, and the cured product can be well peeled off.

The heating temperature is preferably 40 degrees C. or more and 100 degrees C. or less, more preferably 50 degrees C. or more and 80 degrees C. or less.

A peeling force at the time of peeling the cured product from the adhesive surface 12a may be correlated with the holding force of the cured product to hold the foreign matter 13. The peeling force is measured according to JIS Z 0237:2009 “90 degree peeling of adhesive tape/adhesive sheet test method”. For example, the peeling force is preferably 0.2 to 3N/10 mm, and more preferably 0.5 to 2N/10 mm. When the peeling force is not less than the lower limit value of the above range, it is easy to peel off the cured product while the foreign matter 13 is held by the cured product, so that the efficiency in removing foreign matters can be enhanced. When the peeling force is not more than the upper limit value of the above range, the operation of peeling off the cured product is easy, and deformation or breakage of the elastic member 12 can be prevented.

—Foreign Matter to be Removed from the Adhesive Surface—

A foreign matter 13 removed from the adhesive surface 12a of the elastic member 12 is a matter that is different from the adherend to be adhered to the adhesive surface 12a in an intended purpose of the elastic member 12 and may prevent an adhesion of the adherend. For example, when the adherend is an electronic component such as a ceramic capacitor, a chip resistor, a coil, a semiconductor wafer and a glass substrate, the foreign matter 13 is a small piece containing dust, dirt, metal, glass, or silicon.

When the foreign matter 13 is the above-mentioned small piece and its maximum diameter is 5 mm or less, preferably 3 mm or less, more preferably 1 mm or less, the foreign matter 13 can be easily removed by the method of the present embodiment. Here, the maximum diameter of the small piece refers to the diameter of the smallest virtual sphere including the whole small piece. As a method for measuring the maximum diameter of the small piece, there is a method for observing the small piece from above the adhesive surface 12a with a microscope, setting a virtual sphere by substituting it with a circle, and measuring the diameter with a ruler.

The method for regenerating the elastic member 12 according to the present disclosure is not limited to a case where the foreign matter 13 is merely adhered to a surface of the adhesive surface 12a. The method is also effective in a case where a portion of the foreign matter 13 pierces the adhesive surface 12a and remains in the adhesive surface 12a (inside the elastic member 12), so that any foreign matter 13 can be easily removed from the adhesive surface 12a.

1. A method for regenerating an adhesive surface of a component holding jig,
wherein the adhesive surface is regenerated by removing a foreign matter adhering to the adhesive surface of an elastic member of the component holding jig, the method comprising:
disposing, on the adhesive surface, a mask member having: a surface which is in contact with the adhesive surface and has an arithmetic mean roughness Ra of 1.0 μm or less; and an opening through which the adhesive surface is exposed,
disposing a curable resin composition on the adhesive surface and on the mask member and curing the curable resin composition, and
simultaneously peeling off the mask member and a cured product of the curable resin composition.

2. The method according to claim 1, wherein the mask member is a plate-like member made of polyethylene terephthalate.

3. The method according to claim 1, wherein the adhesive surface is made of a silicone rubber or a fluorine-based elastomer.

4. The method according to claim 1, wherein the curable resin composition contains a polyvinyl alcohol, a polyvinyl acetate or a vinyl acetate monomer.

5. The method according to claim 4, wherein the cured product is peeled off while being warmed.

6. The method according to claim 1, wherein the curable resin composition contains a fluorine-based elastomer.

7. The method according to claim 1, wherein the thickness of the curable resin composition after curing is 25 μm or more and 300 μm or less.

8. The method according to claim 1, wherein the foreign matter is a small piece containing dust, dirt, glass, metal, or silicon, and the maximum diameter of the small piece is 5 mm or less.
